(19) United States
(12) Patent Application Publication
(10) Pub. No.: US 2025/0046671 A1
(43) Pub. Date: Feb. 6, 2025

(54) SEMICONDUCTOR APPARATUS AND METHOD FOR MANUFACTURING SEMICONDUCTOR APPARATUS

(71) Applicant: FUJI ELECTRIC CO., LTD., Kanagawa (JP)

(72) Inventor: Koji OSAKI, Matsumoto-city (JP)

(21) Appl. No.: 18/749,557

(22) Filed: Jun. 20, 2024

(30) Foreign Application Priority Data
Aug. 2, 2023 (JP) 2023-126355

(51) Int. Cl. H01L 23/367; H01L 23/00; H01L 23/31; H01L 23/495; H01L 25/065

(52) U.S. Cl. CPC H01L 23/3675; H01L 23/3107; H01L 23/49575; H01L 24/08; H01L 24/32; H01L 25/0652; H01L 2224/08148; H01L 2224/08245; H01L 2224/32145; H01L 2224/32245; H01L 2924/01029; H01L 2924/1032; H01L 2924/182; H01L 2924/351

(57) ABSTRACT

A semiconductor apparatus is provided, comprising: a heat sink; a first semiconductor module cell which is provided above the heat sink; a second semiconductor module cell which is provided above the heat sink and is provided to be in contact with the first semiconductor module cell; and a casing portion which is coupled to the heat sink and accommodates the first semiconductor module cell and the second semiconductor module cell, the first semiconductor module cell having: a first semiconductor chip; and a first encapsulating portion which covers the first semiconductor chip, the second semiconductor module cell having: a second semiconductor chip; and a second encapsulating portion which covers the second semiconductor chip, a side surface of the first encapsulating portion and that of the second encapsulating portion being in contact with each other.

The contents of the following patent application(s) are incorporated herein by reference: NO. 2023-126355 filed in JP on Aug. 2, 2023

### BACKGROUND

### 1. Technical Field

The present invention relates to a semiconductor apparatus and a method for manufacturing the semiconductor apparatus.

### 2. Related Art

Patent Document 1 describes a semiconductor module “which has a housing 122 and a module body MD held in the housing 122”. Patent Document 2 describes a semiconductor module including “a first insulation substrate 102 and a second insulation substrate 110 provided side by side”, in which “a semiconductor element 22 is fixed to a metal pattern 16 by solder 20” and “a semiconductor element 122 is fixed to the metal pattern 114 by solder 120”. Patent Document 3 describes a setup in which “a leaf spring 60 is placed above each semiconductor module 30, 31, and 32”.

### PRIOR ART DOCUMENT

### Patent Document

Patent Document 1: Japanese Patent Application Publication No. 2015-170786
Patent Document 2: Japanese Patent Application Publication No. 2015-216349
Patent Document 3: Japanese Patent Application Publication No. 2014-225571

### BRIEF DESCRIPTION OF THE DRAWINGS

FIG. 1A illustrates an overview of a setup of a semiconductor module 300.

FIG. 1B illustrates a modified example of a setup of the semiconductor module 300.

FIG. 1C illustrates a modified example of a setup of the semiconductor module 300.

FIG. 2 illustrates an example of a setup of a semiconductor module cell 200.

FIG. 3A illustrates an example of a setup of a semiconductor module 300.

FIG. 3B illustrates a modified example of a setup of the semiconductor module 300.

FIG. 4A illustrates an example of a top view of an encapsulating portion 220 having a contact portion 225.

FIG. 4B illustrates an example of the cross section b-b′ in FIG. 4A.

FIG. 4C illustrates an example of the cross section c-c′ in FIG. 4A.

FIG. 5A illustrates a schematic diagram for calculating a stress variance s² in the perpendicular direction acting on the upper surface of a heat sink 260.

FIG. 5B illustrates a relationship between the number of contact surfaces 226 and the stress variance s² in the perpendicular direction.

FIG. 5C illustrates a relationship between the angle of the contact surface 226 and the stress variance s² in the perpendicular direction.

FIG. 6A illustrates a modified example of a setup of the semiconductor module 300.

FIG. 6B illustrates a modified example of a setup of the semiconductor module 300.

FIG. 7A illustrates a flowchart of a method for manufacturing the semiconductor module 300.

FIG. 7B illustrates a flowchart of a method for manufacturing the semiconductor module cell 200.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are imperative to the solving means of the invention.

In the present specification, one side in the thickness direction of the semiconductor chip 100 is referred to as “upper” and the other is referred to as “lower”. Out of two principal surfaces of an element, a substrate, a layer, a film, or other members, one principal surface is referred to as an upper surface, and the other principal surface is referred to as a lower surface. The “upper” and “lower” directions are not limited to the gravitational direction. In the present example, the up-down direction is referred to as a Z axis direction, and two directions orthogonal to each other in a plane perpendicular to the Z axis direction are respectively referred to as an X axis direction and a Y axis direction. The XYZ axes constitute a right-handed system. The top view refers to the semiconductor chip 100 seen from the positive direction of the Z axis.

Each example implementation shows an example in which a first conductivity type is an N type and a second conductivity type is a P type, but the first conductivity type may be the P type and the second conductivity type may be the N type. In this case, conductivity types of the substrate, the layer, a region, or the like in each example implementation respectively have opposite polarities. Each of the layers and regions noted with N or P means that electrons or holes are majority carriers. In addition, the signs + and − affixed to N and P respectively mean that the layers or regions have higher doping concentrations and lower doping concentrations than the layers or regions without + and −.

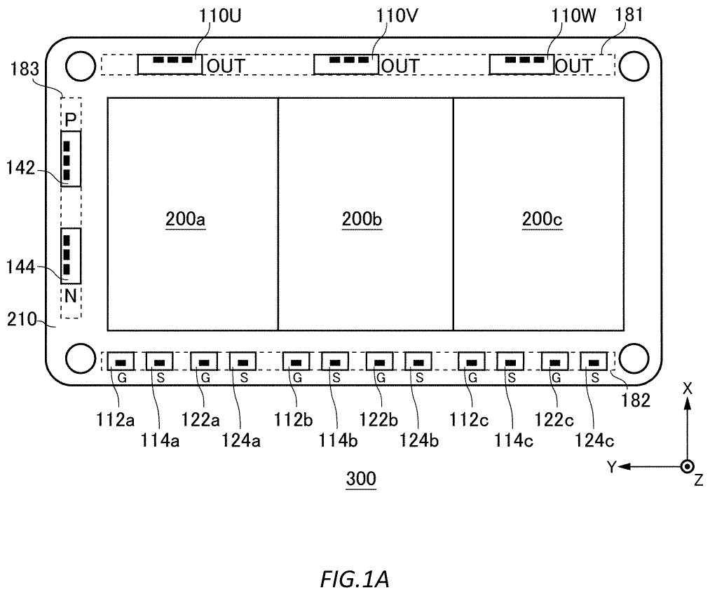

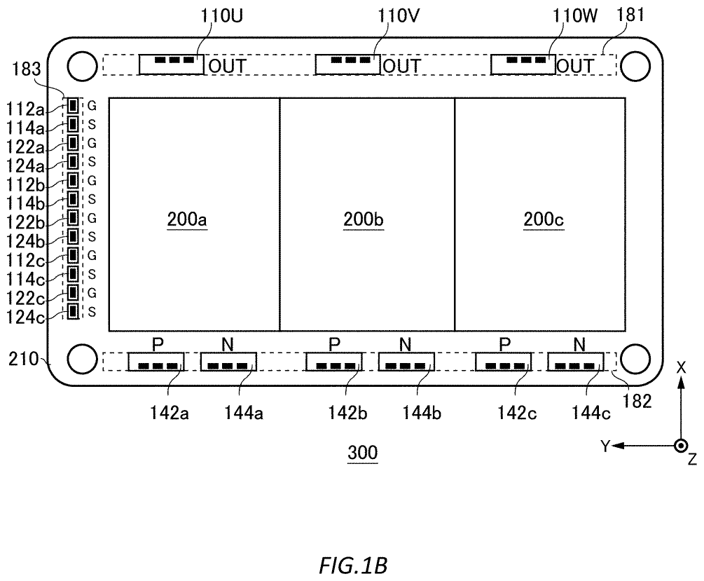

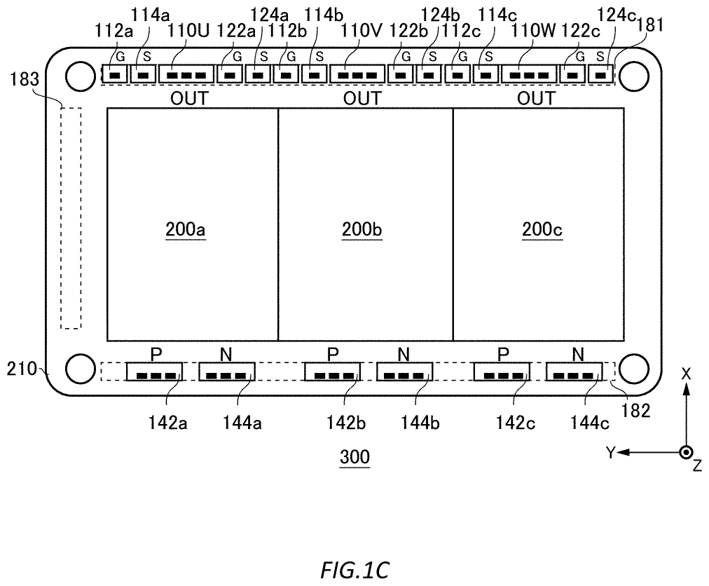

FIG. 1A illustrates an overview of a setup of a semiconductor module 300. The semiconductor module 300 includes a plurality of semiconductor module cells 200. The semiconductor module cell 200 in the present example includes, but is not limited to, three semiconductor module cell 200a to semiconductor module cell 200c. The semiconductor module 300 in the present example includes an output terminal 110, a gate external terminal 112, an auxiliary source external terminal 114, a gate external terminal 122, an auxiliary source external terminal 124, a positive terminal 142, and a negative terminal 144 as external terminals.

The semiconductor module 300 may be applied to a power conversion apparatus such as a power module constituting an inverter circuit. For example, when the semiconductor module 300 constitutes a three-phase inverter circuit, the semiconductor module cell 200a to semiconductor module cell 200c may correspond to the U-phase, the V-phase, and the W-phase of the three-phase inverter circuit, respectively.

The semiconductor module cell 200 may have the semiconductor chip 100 described below. The detail of the semiconductor module cell 200 is described below. The semiconductor module cell 200 is accommodated in the casing portion 210 of the semiconductor module 300. The side walls of a plurality of adjacent semiconductor module cells 200 may be in contact with each other.

An output terminal 110 is an external terminal for electrical connection with a load provided outside the semiconductor module 300. The output terminals 110 of the present example has three external terminals: an output terminal 110U, an output terminal 110V, and an output terminal 110W, which correspond to the U to W phases, respectively. The output terminal 110 is provided on one predetermined side of the semiconductor module 300. Among four sides of the semiconductor module 300, the output terminals 110 of the present example are provided on a side that extends in the Y axis direction on a positive side of an X axis direction. The output terminals 110 of the present example are provided in a first placement region 181 that extends in the Y axis direction. The plurality of output terminals 110 are arranged in the Y axis direction in the first placement region 181.

The three output terminals 110U to 110W are arranged in the Y axis direction such that they are opposed to the semiconductor module cell 200a to semiconductor module cell 200c, respectively. Note that, the number and an arrangement method of the output terminals 110 are not limited to these.

The gate external terminals 112, the auxiliary source external terminals 114, the gate external terminals 122, and the auxiliary source external terminals 124 are examples of control terminals which control the operation of the semiconductor module 300. The control terminal of the present example is provided on a side opposite to the side on which the output terminal 110 is provided. The control terminal of the present example is provided on a side extending in the Y axis direction on the negative side of the semiconductor module 300 in the X axis direction.

The gate external terminals 112 have three gate external terminals 112a to 112c corresponding to the semiconductor module cell 200a to semiconductor module cell 200c. The auxiliary source external terminals 114 have three auxiliary source external terminals 114a to 114c corresponding to the semiconductor module cell 200a to semiconductor module cell 200c. The plurality of gate external terminals 112 of the present example are provided in a second placement region 182 that extends in the Y axis direction. The plurality of auxiliary source external terminals 114 of the present example are provided in the second placement region 182 that extends in the Y axis direction.

Similarly, the gate external terminals 122 have three gate external terminals 122a to 122c corresponding to the semiconductor module cell 200a to semiconductor module cell 200c. The auxiliary source external terminals 124 have three auxiliary source external terminals 124a to 124c corresponding to the semiconductor module cell 200a to semiconductor module cell 200c. The plurality of gate external terminals 122 of the present example are provided in a second placement region 182 that extends in the Y axis direction. The plurality of auxiliary source external terminals 124 of the present example are provided in the second placement region 182 that extends in the Y axis direction.

The positive terminal 142 and the negative terminal 144 are provided on one predetermined side of the semiconductor module 300. The positive terminal 142 and the negative terminal 144 of the present example are provided on a side orthogonal to the side on which the output terminal 110 is provided. The positive terminal 142 and the negative terminal 144 may be provided on a side orthogonal to the side on which the control terminal such as the gate external terminal 112 is provided. The positive terminal 142 and the negative terminal 144 of the present example are provided on a side that extends in the X axis direction, on a positive side of the Y axis direction of the semiconductor module 300.

The positive terminal 142 and the negative terminal 144 may be provided on a side which extends in the X axis direction, on the negative side of the Y axis direction. The positive terminal 142 and the negative terminal 144 of the present example are provided in a third placement region 183 that extends in the X axis direction. The third placement region 183 may be placed side by side with the plurality of legs in the Y axis direction. In other words, the third placement region 183 may be provided opposing the plurality of legs in the Y axis direction. The positive terminal 142 and the negative terminal 144 are arranged in the X axis direction in the third placement region 183.

FIG. 1B illustrates a modified example of a setup of the semiconductor module 300. In FIG. 1B, the placement of the control terminal such as the gate external terminal 112, the positive terminal 142, and the negative terminal 144 is different from that of the example illustrated in FIG. 1A.

The positive terminal 142 and the negative terminal 144 are provided on one predetermined side of the semiconductor module 300. The positive terminal 142 and the negative terminal 144 of the present example are provided on a side opposed to the side on which the output terminal 110 is provided. The positive terminal 142 and the negative terminal 144 may be provided on a side orthogonal to the side on which the control terminal such as the gate external terminal 112 is provided. The positive terminal 142 and the negative terminal 144 are provided on a side which extends in the Y axis direction, on the negative side of the X axis direction of the semiconductor module 300.

The positive terminal 142 has three positive terminals 142a to 142c corresponding to the semiconductor module cell 200a to the semiconductor module cell 200c. The negative terminal 144 has three negative terminals 144a to 144c corresponding to the semiconductor module cell 200a to the semiconductor module cell 200c. The positive terminal 142 and the negative terminal 144 in the present example are provided in the second placement region 182 which extends in the Y axis direction. It is noted that the number and the arrangement method of the positive terminal 142 and the negative terminal 144 are not limited thereto.

The gate external terminals 112, the auxiliary source external terminals 114, the gate external terminals 122, and the auxiliary source external terminals 124 are examples of control terminals which control the operation of the semiconductor module 300. The control terminal in the present example is provided on a side orthogonal to the side on which the output terminal 110 is provided. The control terminal in the present example is provided on a side which extends in the X axis direction, on the positive side of the Y axis direction of the semiconductor module 300.

A plurality of gate external terminals 112 may be provided corresponding to a plurality of semiconductor module cells 200. The gate external terminals 112 have three gate external terminals 112a to 112c corresponding to the semiconductor module cell 200a to the semiconductor module cell 200c. A plurality of auxiliary source external terminals 114 may be provided corresponding to a plurality of semiconductor module cells 200. The auxiliary source external terminals 114 have three auxiliary source external terminals 114a to 114c corresponding to the semiconductor module cell 200a to the semiconductor module cell 200c. The plurality of gate external terminals 112 in the present example are provided on the third placement region 183 which extends in the X axis direction. The plurality of auxiliary source external terminals 114 in the present example are provided in the third placement region 183 which extends in the X axis direction.

Similarly, the gate external terminals 122 have three gate external terminals 122a to 122c corresponding to the semiconductor module cell 200a to the semiconductor module cell 200c. The auxiliary source external terminals 124 have three auxiliary source external terminals 124a to 124c corresponding to the semiconductor module cell 200a to semiconductor module cell 200c. The plurality of gate external terminals 122 in the present example are provided in the third placement region 183 which extends in the X axis direction. The plurality of auxiliary source external terminals 124 in the present example are provided in the third placement region 183 which extends in the X axis direction.

FIG. 1C illustrates a modified example of a setup of the semiconductor module 300. In FIG. 1C, the placement of the control terminal such as the gate external terminal 112 is different from the example illustrated in FIG. 1B.

The control terminal in the present example is provided on the same side as the side on which the output terminal 110 is provided. In other words, the gate external terminal 112, the auxiliary source external terminal 114, the gate external terminal 122, and the auxiliary source external terminal 124 are provided in the first placement region 181. As described with reference to FIG. 1A, each of the control terminals may be provided in a quantity of three corresponding to the semiconductor module cell 200a to the semiconductor module cell 200c.

The control terminal may be provided on the side which is opposed to the side on which the output terminal 110 is provided. In other words, the gate external terminal 112, the auxiliary source external terminal 114, the gate external terminal 122, and the auxiliary source external terminal 124 may be provided in the second placement region 182 in which the positive terminal 142 and the negative terminal 144 are provided. All external connection terminals are placed on the long side of the semiconductor module 300 to facilitate replacement in the case of failure of the semiconductor module cell 200.

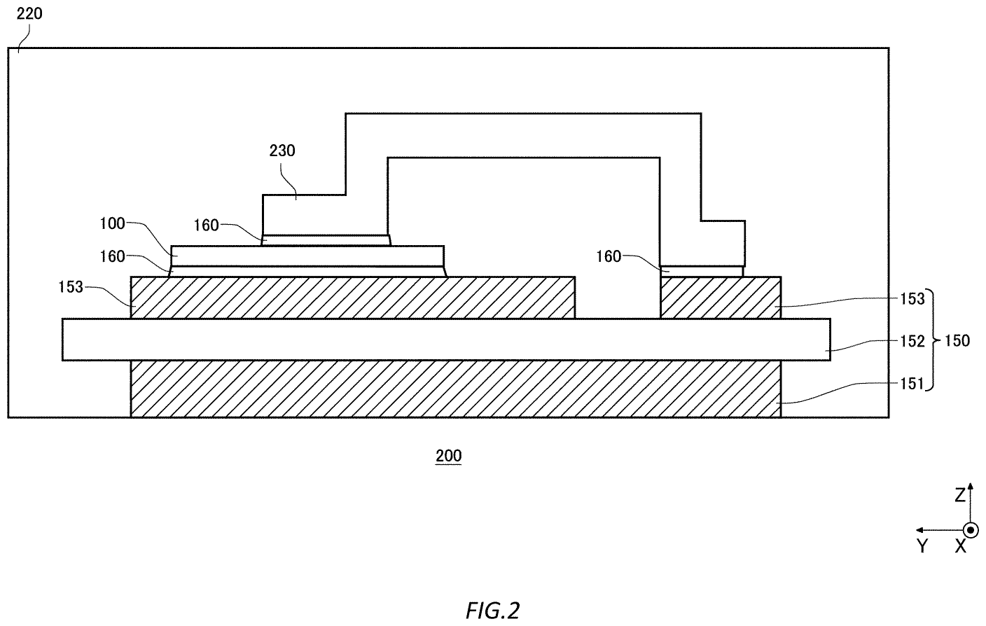

FIG. 2 illustrates an example of a setup of the semiconductor module cell 200. The semiconductor module cell 200 in the present example includes a semiconductor chip 100, a laminated substrate 150, an encapsulating portion 220, and a lead frame 230.

The laminated substrate 150 may be a direct copper bonding (DCB) substrate or an active metal brazing (AMB) substrate. A plurality of semiconductor chips 100 may be provided on the laminated substrate 150. The laminated substrate 150 includes a first metal layer 151, an insulating plate 152, and a second metal layer 153.

The insulating plate 152 is formed of an insulating material such as ceramics including alumina (Al₂O₃), aluminum nitride (AlN), silicon nitride (Si₃N₄), or the like. The first metal layer 151 may be provided on the lower surface of the insulating plate 152 and be fixed to the upper surface of the substrate base via a coupling member 160.

The second metal layer 153 is a conductive member provided on the upper surface of the insulating plate 152. The second metal layer 153 may include metal wiring, a pad, or the like. The first metal layer 151 and the second metal layer 153 may be formed of a board including a metal material such as copper and copper alloy. The material of the second metal layer 153 may be the same as or may be different from the material of the first metal layer 151. The first metal layer 151 and the second metal layer 153 may be fixed to the surface of the insulating plate 152 through solder, wax, or the like. The second metal layer 153 is electrically connected to the semiconductor chip 100 through the coupling member 160.

The coupling member 160 connects the pad included in the second metal layer 153 to the collector electrode 24 of the semiconductor chip 100. For example, the material of the coupling member 160 is Sn—Cu-based or Sn—Sb-based solder.

The lead frame 230 electrically connects the semiconductor chip 100 to an external control apparatus or the like. When incorporated into the semiconductor module 300, the lead frame 230 is provided to pass through the casing portion 210 and connect to the external terminals.

The encapsulating portion 220 is provided so as to cover the semiconductor chip 100. The encapsulating portion 220 is composed of an insulating material. Thus, insulation failure between conductive components in the semiconductor module cell 200 can be avoided. As an example, the encapsulating portion 220 includes silicone gel material or fluorine gel material.

The encapsulating portion 220 is provided up to a position covering the upper surface of the lead frame 230. The film thickness from the lower surface to the upper surface of the encapsulating portion 220 may be a film thickness which does not expose each element encapsulated inside the encapsulating portion 220 when a contact portion 225 is formed as described below.

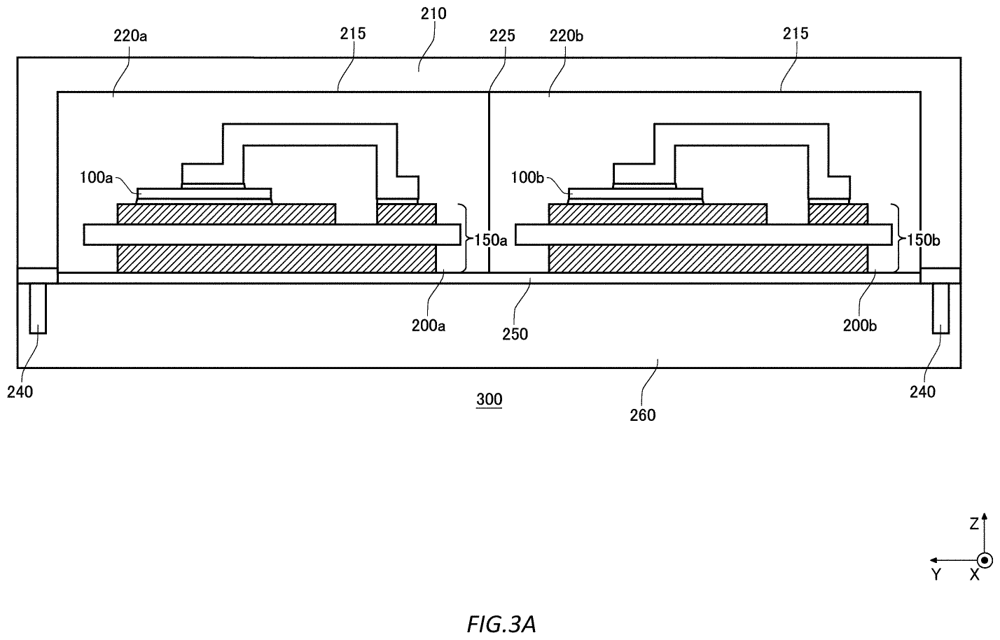

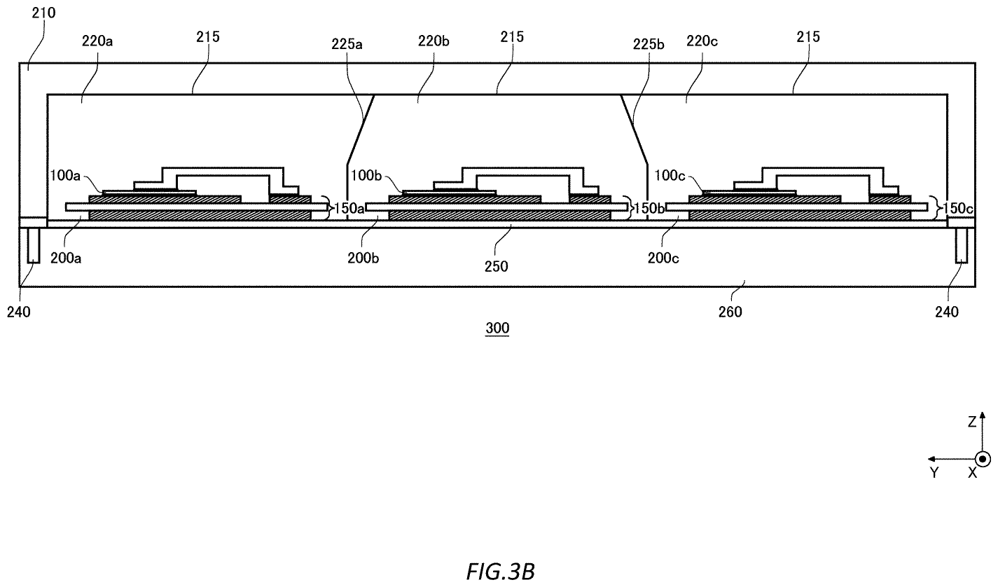

FIG. 3A illustrates an example of a setup of the semiconductor module 300 in the present example. The semiconductor module 300 in the present example includes two semiconductor module cells 200. The semiconductor module 300 may include a first semiconductor module cell 200a and a second semiconductor module cell 200b. The semiconductor module 300 in the present example includes a plurality of semiconductor module cells 200, a casing portion 210, a coupling portion 240, an interposed portion 250, and a heat sink 260.

The first semiconductor module cell 200a is provided above the heat sink 260. The first semiconductor module cell 200a may have a first laminated substrate 150a, a first semiconductor chip 100a mounted on the first laminated substrate 150a, and a first encapsulating portion 220a covering the first semiconductor chip 100a. The detail of the setup of the first semiconductor module cell 200a may be the same as that of the semiconductor module cell 200 described in FIG. 2.

The second semiconductor module cell 200b is provided above the heat sink 260 and in contact with the first semiconductor module cell 200a. The second semiconductor module cell 200b may have a second laminated substrate 150b, a second semiconductor chip 100b mounted on the second laminated substrate 150b, and a second encapsulating portion 220b covering the second semiconductor chip 100b. The detail of the setup of the second semiconductor module cell 200b may be the same as or may be different from the setup of the first semiconductor module cell 200a.

The side surfaces of the plurality of semiconductor module cells 200 may be in contact with each other. In the present example, the side surface of the first encapsulating portion 220a is in contact with the side surface of the second encapsulating portion 220b. Thus, a frictional force acts on the contact surface of the semiconductor module cell 200, the semiconductor module cell 200 is uniformly pressed against the heat sink 260, and the cooling variation in the entire semiconductor module 300 is reduced.

The casing portion 210 accommodates the semiconductor module cell 200. The casing portion 210 may accommodate the first semiconductor module cell 200a and the second semiconductor module cell 200b. The casing portion 210 may be coupled to the heat sink 260. Coupling the casing portion 210 to the heat sink 260 may refer to fixing it to the heat sink 260 by using a screw or the like or may refer to sticking it to the heat sink 260 by using adhesive or the like.

The casing portion 210 may have an attachment portion for attaching the coupling portion 240. The casing portion 210 in the present example has a hole through which the coupling portion 240 passes.

The casing portion 210 is provided to be separated from the laminated substrate 150. The casing portion 210 in the present example is provided to be separated from the first laminated substrate 150a and the second laminated substrate 150b. An encapsulating portion 220 may be provided between the casing portion 210 and the laminated substrate 150. The pressing force to be applied to the semiconductor module cell 200 can be made uniform by providing the casing portion 210 to be separated from the laminated substrate 150 with the encapsulating portion 220 interpolated.

The pressing portion 215 presses on the upper surface of the encapsulating portion 220. The pressing portion 215 may press on the upper surfaces of the first encapsulating portion 220a and the second encapsulating portion 220b. Since the pressing portion 215 presses on the upper surface of the encapsulating portion 220, the semiconductor module cell 200 is pushed against the heat sink 260, thereby improving the cooling efficiency. The pressing portion in the present example is an inner wall of the casing portion 210. In other words, the inner wall of the casing portion 210 may be in contact with the upper surface of the first encapsulating portion 220a and the upper surface of the second encapsulating portion 220b.

The plurality of encapsulating portions 220 may be provided in a mutually separatable manner with the side surfaces being in contact with each other. In the present example, the first encapsulating portion 220a and the second encapsulating portion 220b are provided in a mutually separatable manner with the side surfaces being in contact with each other. The plurality of encapsulating portions 220 may be individually molded rather than integrally molded.

The plurality of encapsulating portions 220 have a contact portion 225 consisting of one or more contact surfaces where the side surfaces are in contact with each other. The first encapsulating portion 220a and the second encapsulating portion 220b in the present example have a contact portion 225 in a region where the side surfaces are in contact with each other. Since the plurality of encapsulating portion 220 have the contact portion 225, a frictional force acts between the adjacent encapsulating portions 220 and a pressing force applied to one of the encapsulating portion 220 is also applied to the other encapsulating portion 220, making the pressing force applied to each encapsulating portion 220 uniform.

The coupling portion 240 couples the casing portion 210 to the heat sink 260. The casing portion 210 may have a plurality of coupling portions 240. The plurality of coupling portions 240 may be provided at symmetric positions of the casing portion 210. The plurality of coupling portions 240 in the present example are provided at four corners of the casing portion 210. By providing the coupling portion 240 at symmetric positions, the pressing force applied by the pressing portion 215 to the encapsulating portion 220 can be made uniform and the pressing force applied to the semiconductor module cell 200 can be made uniform.

The interposed portion 250 is provided on the upper surface of the heat sink 260. The interposed portion 250 may be provided between the upper surface of the heat sink 260 and the lower surface of the laminated substrate 150. The interposed portion 250 may be composed of organic insulating material. The interposed portion 250 may be thermal interface material (TIM). Thus, the cooling efficiency of the semiconductor module 300 is improved.

The interposed portion 250 is grease, as an example. The grease may be silicone grease or may be oil compound. The interposed portion 250 being composed of grease improves the ease of replacement in an event such as a failure of the semiconductor module cell 200.

The interposed portion 250 may be adhesive or may be a resin sheet. Thus, the semiconductor module cell 200 can be fixed to the upper surface of the heat sink 260.

The plurality of semiconductor module cells 200 may be provided above the common interposed portion 250. The first semiconductor module cell 200a and the second semiconductor module cell 200b in the present example are provided above the common interposed portion 250. Thus, the cooling variation in the entire semiconductor module 300 is reduced.

The heat sink 260 cools the semiconductor module cell 200. The heat sink 260 may be composed of a material with high heat transfer efficiency. As an example, the heat sink 260 is composed of stainless steel. The heat sink 260 may be connected to an external cooling apparatus, which is not illustrated, to be cooled.

FIG. 3B illustrates a modified example of a setup of the semiconductor module 300 in the present example. The semiconductor module 300 in the present example includes three semiconductor module cells 200. The semiconductor module 300 may include a first semiconductor module cell 200a, a second semiconductor module cell 200b, and a third semiconductor module cell 200c.

The third semiconductor module cell 200c may have a third laminated substrate 150c, a third semiconductor chip 100c mounted on the third laminated substrate 150c, and a third encapsulating portion 220c covering the third semiconductor chip 100c. The detail of a setup of the third semiconductor module cell 200c may be the same as or different from the setup of the first semiconductor module cell 200a and the second semiconductor module cell 200b.

The side surface forming the contact portion 225 may include an inclined side surface. The plurality of encapsulating portions 220 in the present example have a contact portion 225 including one or more contact surfaces 226 where the inclined side surfaces are in contact with each other. Since the contact portion 225 includes inclined side surfaces, among the adjacent encapsulating portions 220, the pressing force applied to one of the encapsulating portions 220 can be more efficiently applied to the other encapsulating portion 220.

The first encapsulating portion 220a and the second encapsulating portion 220b in the present example has a contact portion 225a including one or more contact surfaces where inclined side surfaces are in contact with each other. Thus, a part of the pressing force applied to the first semiconductor module cell 200a is also applied to the second semiconductor module cell 200b, and the first semiconductor module cell 200a and the second semiconductor module cell 200b are uniformly pressed against the heat sink 260, thereby reducing the cooling variation in the entire semiconductor module 300.

The second encapsulating portion 220b and the third encapsulating portion 220c in the present example have a contact portion 225b including one or more contact surfaces where inclined side surfaces are in contact with each other. The side wall of the third encapsulating portion 220c may be in contact with at least one of the side wall of the first encapsulating portion 220a or the side wall of the second encapsulating portion 220b. Thus, the first semiconductor module cell 200a, the second semiconductor module cell 200b, and the third semiconductor module cell 200c are uniformly pressed against the heat sink 260 and the cooling variation in the entire semiconductor module 300 is reduced.

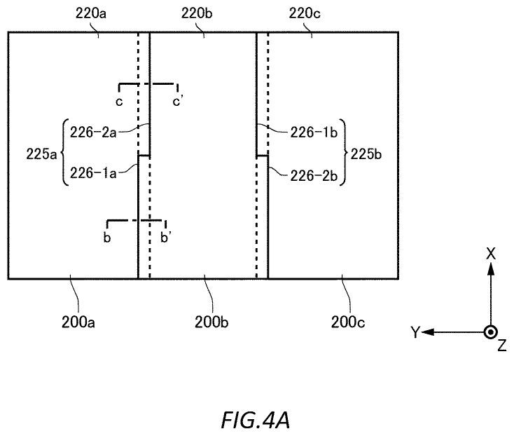

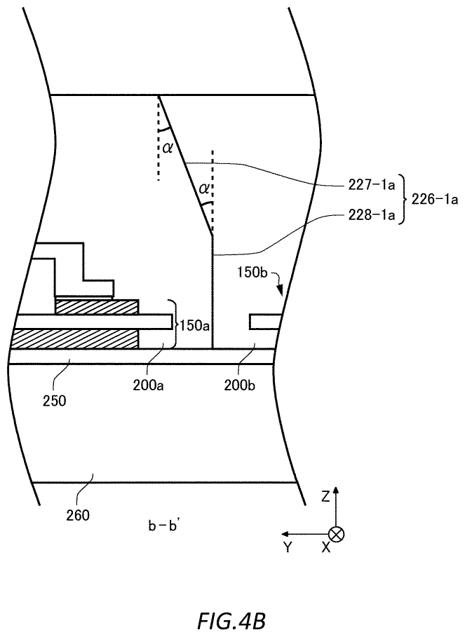

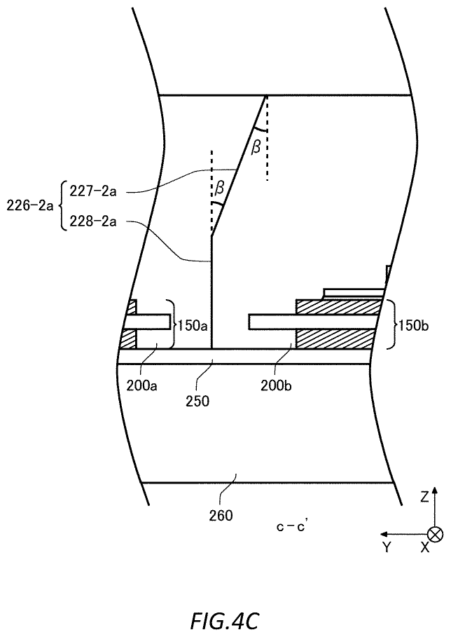

FIG. 4A is an example of a top view of the encapsulating portion 220 having the contact portion 225. The contact portion 225 may have the plurality of contact surfaces 226. The contact portion 225a in the first encapsulating portion 220a and the second encapsulating portion 220b in the present example has a first contact surface 226-1a and a second contact surface 226-2a. The contact portion 225b in the second encapsulating portion 220b and the third encapsulating portion 220c in the present example has a first contact surface 226-1b and a second contact surface 226-2b.

The contact surface 226 may include at least one of the inclined section 227, which is the side surface inclined relative to the laminating direction of the laminated substrate 150, or the vertical portion 228, which is the side surface parallel to the laminating direction. In the example illustrated in FIG. 3A, the contact surface 226 includes a vertical portion 228 and does not include the inclined section 227. In the example illustrated in FIG. 3B, the contact surface 226 includes both the inclined section 227 and the vertical portion 228. The inclined section 227 and the vertical portion 228 are described below.

The contact portion 225 in the present example has two contact surfaces 226. The contact portion 225 may have one contact surface 226 and may have three or more contact surfaces 226. The number of the contact surfaces 226 which the contact portion 225a in the first encapsulating portion 220a and the second encapsulating portion 220b has may be the same as or may be different from the number of the contact surfaces 226 which the contact portion 225b in the second encapsulating portion 220b and the third encapsulating portion 220c has.

In the present specification, the number of contact surfaces 226 which the contact portion 225 has may be the number of regions where inclined side surfaces of the adjacent encapsulating portions 220 are in contact with each other with different angles in the contact portion 225, or may be the number of regions where they are in contact with each other with different shapes. If the contact surface 226 does not have the inclined section 227, the number of the contact surface 226 that the contact portion 225 has is one. In the present example, the contact portion 225a has two contact surfaces 226: a first contact surface 226-1a, which is formed as a result of the second encapsulating portion 220b extending above the first encapsulating portion 220a, and a second contact surface 226-2a, which is formed as a result of the first encapsulating portion 220a extending above the second encapsulating portion 220b.

FIG. 4B is a diagram illustrating an example of the cross section b-b′ in FIG. 4A. The cross section b-b′ is a cross section which is a boundary between the first encapsulating portion 220a and the second encapsulating portion 220b and passes through the first contact surface 226-1a.

One or more contact surfaces where the inclined side surfaces are in contact with each other may have a first contact surface 226-1a. The first contact surface 226-1a includes a first inclined section 227-1a composed of an inclined side surface that the first encapsulating portion 220a has and an inclined side surface that the second encapsulating portion 220b has, and a first vertical portion 228-1a composed of a vertical plane that the first encapsulating portion 220a has and a vertical plane that the second encapsulating portion 220b has.

The angle of the inclined side surface that the first encapsulating portion 220a has relative to the laminating direction of the first laminated substrate 150a and the second laminated substrate 150b may be the same as or be different from the angle of the inclined side surface that the second encapsulating portion 220b has. The angle of the inclined side surface that the first encapsulating portion 220a has in the present example is the same as the angle of the inclined side surface that the second encapsulating portion 220b has.

The first inclined section 227-1a constituting the first contact surface 226-1a may have a predetermined angle relative to the laminating direction of the first laminated substrate 150a and the second laminated substrate 150b. The first inclined section 227-1a in the present example has a predetermined angle α relative to the laminating direction of the first laminated substrate 150a and the second laminated substrate 150b. In the present specification, the angle of the first contact surface 226-1a may refer to the predetermined angle α that the first inclined section 227-1a has. The predetermined angle α may be 10° or more and 90° or less. The predetermined angle α may be 90° or more and 180° or less.

The first inclined section 227-1a may be a plane or may be a curved surface. The shape of the first inclined section 227-1a in the Y—Z cross section may be a linear shape, may be a polyline shape, or may be a curvilinear shape. Regardless of the shape of the first inclined section 227-1a, a pressing force applied to the upper surface of the second encapsulating portion 220b can be applied to the first encapsulating portion 220a and the pressing force can be distributed.

FIG. 4C is a diagram which illustrates an example of the cross section c-c′ in FIG. 4A. The cross section c-c′ is a cross section which is a boundary between the first encapsulating portion 220a and the second encapsulating portion 220b and is passing through the second contact surface 226-2a. The second contact surface 226-2a includes a second inclined section 227-2a composed of an inclined side surface that the first encapsulating portion 220a has and an inclined side surface that the second encapsulating portion 220b has and a second vertical portion 228-2a composed of a vertical plane that the first encapsulating portion 220a has and a vertical plane that the second encapsulating portion 220b has.

The one or more contact surfaces where the inclined side surfaces are in contact with each other may have a second contact surface 226-2a. The second inclined section 227-2a constituting the second contact surface 226-2a may have a predetermined angle relative to the laminating direction of the first laminated substrate 150a and the second laminated substrate 150b. The second inclined section 227-2a in the present example has a predetermined angle β relative to the laminating direction of the first laminated substrate 150a and the second laminated substrate 150b. In the present specification, the angle of the second contact surface 226-2a may refer to a predetermined angle β that the second inclined section 227-2a has. The predetermined angle β may be −90° or more and −10° or less. The predetermined angle β may be −180° or more and −90° or less.

The second inclined section 227-2a may be a plane or may be a curved surface. The shape of the second inclined section 227-2a in the Y—Z cross section may be a linear shape, may be a polyline shape, or may be a curvilinear shape. Regardless of the shape of the second inclined section 227-2a, the pressing force applied to the upper surface of the first encapsulating portion 220a can be applied to the second encapsulating portion 220b and the pressing force can be distributed.

The absolute value of the predetermined angle α that the first inclined section 227-1a has may be the same as or may be different from the predetermined angle β that the second inclined section 227-2a has. In the present example, the absolute value of the angle of the first inclined section 227-1a is the same as that of the second inclined section 227-2a.

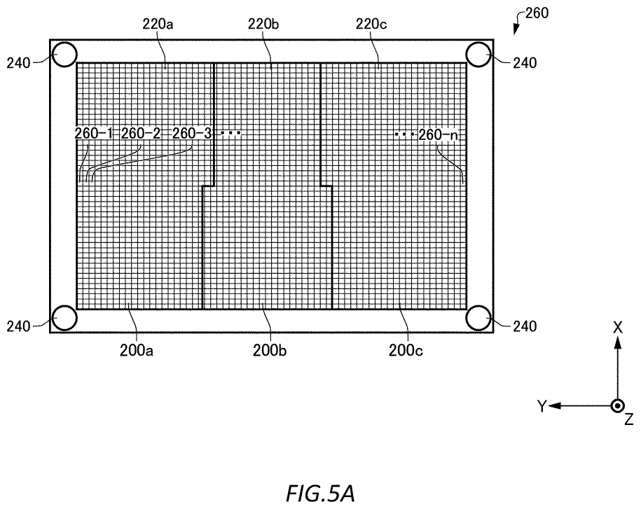

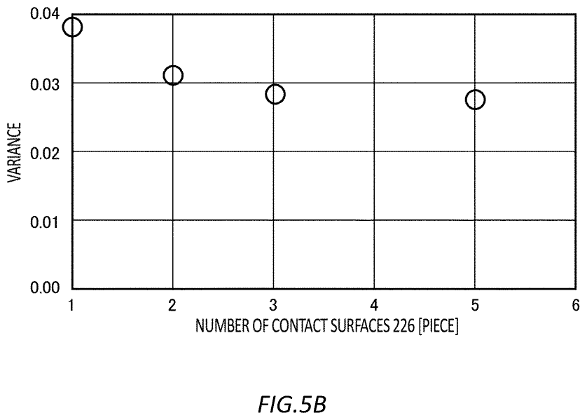

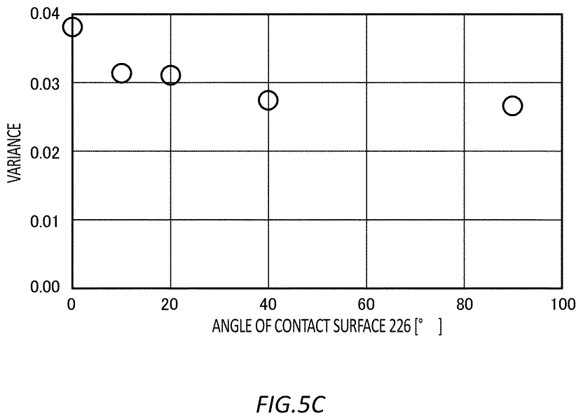

FIG. 5A is a model diagram for calculating a stress variance s² in the perpendicular direction acting on the upper surface of the heat sink 260. The casing portion 210 accommodating three semiconductor module cells 200 is mounted on the upper surface of the heat sink 260 and load in the perpendicular direction is applied at four corners of the casing portion 210 via the coupling portions 240. After that, the region on the upper surface of the heat sink 260 is divided into n regions, which are in the order of 260-1, 260-2, 260-3, . . . , 260-n, and the stress in the perpendicular direction on each divided region is calculated. Herein, n is any natural number determined depending on a simulation scale and a simulation time. Then, the stress variance s² in the perpendicular direction is calculated from each of the obtained stress values by using the formula described in the following Formula 1:

$${s}^{2} = \frac{1}{n} {\sum }_{n} {( {σ}_{n} - {σ}_{avg} )}^{2} . \qquad ( Formula 1 )$$

In this formula, σₙ indicates a magnitude of the stress in the perpendicular direction on each region 260-n and σ_{avg} indicates the average value of the stress in the perpendicular direction.

FIG. 5B is a diagram representing a relationship between the number of the contact surface 226 that the contact portion 225 has and the variance of the stress in the perpendicular direction acting on the upper surface of the heat sink 260. FIG. 5B plots the number of the contact surfaces 226 that the contact portion 225 has on the horizontal axis and the variance of the stress in the perpendicular direction acting on the upper surface of the heat sink 260 on the vertical axis.

It can be seen that the contact portion 225 having one or more inclined sections 227 has a lower variance than the contact portion 225 having no inclined section 227. Since the contact portion 225 has the inclined section 227, the pressing force applied to the plurality of semiconductor module cells 200 can be made uniform.

FIG. 5C is a diagram representing a relationship between the angle of the contact surface 226 that the contact portion 225 has and the variance of the stress in the perpendicular direction acting on the upper surface of the heat sink 260. FIG. 5B plots the angle of the contact surface 226 that the contact portion 225 has on the horizontal axis and the variance of the stress in the perpendicular direction acting on the upper surface of the heat sink 260 on the vertical axis. In the present example, the angle of the contact surface 226 refers to the predetermined angles α and β illustrated in FIG. 4B and FIG. 4C. It is noted that, during the calculation process of the stress variance, the calculation is performed assuming that α and β are the same.

It can be seen that when the angle of the contact surface 226 that the contact portion 225 has are 10°, 20°, 40°, and 90°, the variance is smaller than when the angle of the contact surface 226 is 0°. By setting the angle of the contact surface 226 that the contact portion 225 has to be 10° or more and 90° or less, the pressing force applied to the plurality of semiconductor module cell 200 can be made uniform.

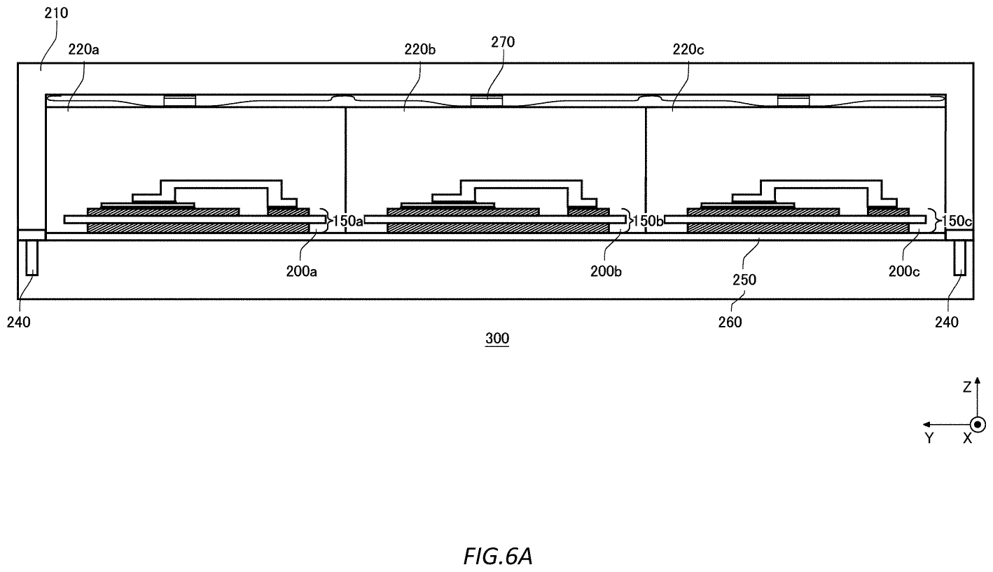

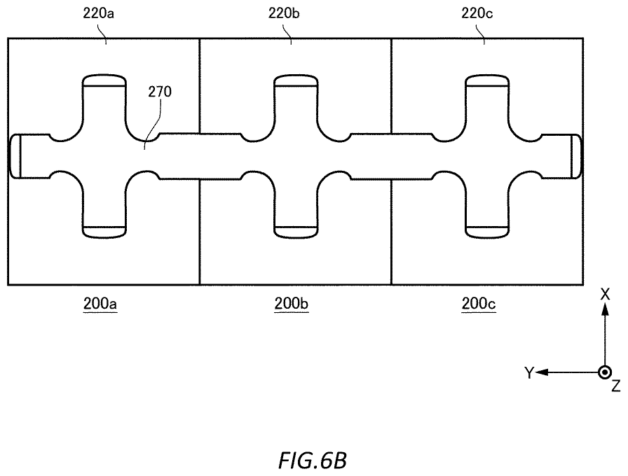

FIG. 6A illustrates a modified example of a setup of the semiconductor module 300 in the present example. The semiconductor module 300 in the present example includes three semiconductor module cells 200. The semiconductor module 300 may have a spring portion 270 between the casing portion 210 and the encapsulating portion 220. The semiconductor module 300 in the present example has the spring portion 270 provided between the casing portion 210, and the first encapsulating portion 220a, the second encapsulating portion 220b, and the third encapsulating portion 220c, as the pressing portion 215.

The spring portion 270 applies the pressing force from the inner wall of the casing portion 210 to the encapsulating portion 220. The spring portion 270 may be a leaf spring. The spring portion 270 is composed of elastic material that can apply the pressing force from the inner wall of the casing portion 210 to the encapsulating portion 220. The material of the spring portion 270 may be a metal material such as carbon steel, stainless steel, nickel alloy and titanium alloy, or may be a non-metal material such as natural rubber, plastic, and ceramic. By providing the spring portion 270, the pressing force applied to the encapsulating portion 220 can be made uniform.

FIG. 6B illustrates an example of a top view of the modified example illustrated in FIG. 6A. For simplicity, the casing portion 210 is omitted.

The spring portion 270 may be commonly provided for each of the plurality of encapsulating portions 220, or it may be individually provided. The spring portion 270 in the present example is commonly provided for the first encapsulating portion 220a, the second encapsulating portion 220b, and the third encapsulating portion 220c. The spring portion 270 being commonly provided for each of the plurality of encapsulating portions 220 may refer to a single spring portion 270 being provided to press each of the plurality of encapsulating portions 220 in the semiconductor module 300.

The spring portion 270 may be configured to have an approximately cross-shape for each of the plurality of encapsulating portions 220 in the top view. Thus, the pressing force applied from the casing portion 210 can be uniformly applied to the encapsulating portion 220.

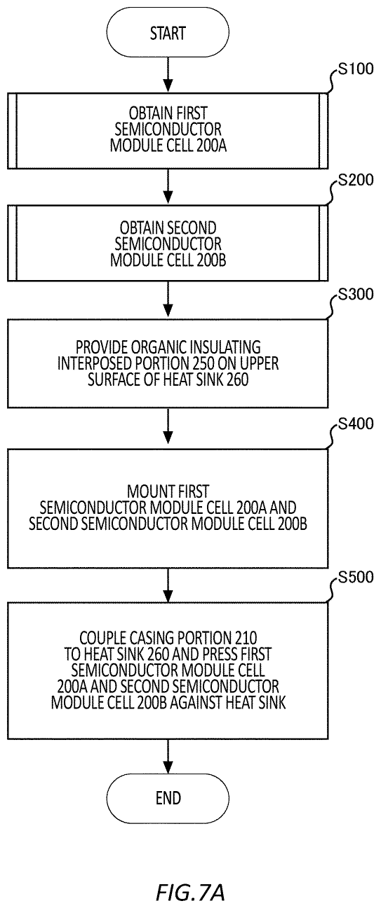

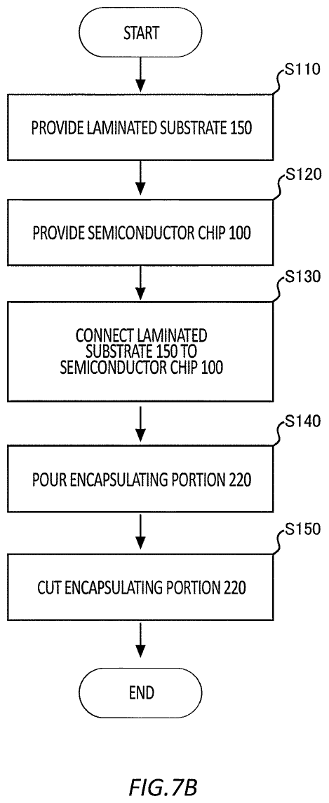

FIG. 7A illustrates a flowchart for a method for manufacturing the semiconductor module 300. The method for manufacturing the semiconductor module 300 in the present example includes step S100 for obtaining the first semiconductor module cell 200a and step S200 for obtaining the second semiconductor module cell 200b. The method for manufacturing the semiconductor module 300 in the present example may include step S300 for providing the organic insulating interposed portion 250 on the upper surface of the heat sink 260. The method for manufacturing the semiconductor module 300 in the present example includes a step S400 for mounting the first semiconductor module cell 200a and the second semiconductor module cell 200b. The method for manufacturing the semiconductor module 300 in the present example includes step S500 for coupling the casing portion 210 to the heat sink 260 and pressing the first semiconductor module cell 200a and the second semiconductor module cell 200b against the heat sink 260 by the pressing portion 215 of the casing portion 210.

Step S100 for obtaining the first semiconductor module cell 200a may include a step for manufacturing the first semiconductor module cell 200a. Step S200 for obtaining the second semiconductor module cell 200b may include a step for manufacturing the second semiconductor module cell 200b. The actor manufacturing the first semiconductor module cell 200a and the second semiconductor module cell 200b may be the same as or may be different from the actor manufacturing the semiconductor module 300 in the present example.

The first semiconductor module cell 200a obtained in step S100 has a first laminated substrate 150a, a first semiconductor chip 100a mounted on the first laminated substrate 150a, and a first encapsulating portion 220a covering the first semiconductor chip 100a. Similarly, the second semiconductor module cell 200b obtained in step S200 has a second laminated substrate 150b, a second semiconductor chip 100b mounted on the second laminated substrate 150b, and a second encapsulating portion 220b covering the second semiconductor chip 100b.

In step S300, the interposed portion 250 of the organic insulating is provided on the upper surface of the heat sink 260. Thus, the heat transfer efficiency between the semiconductor module cell 200 and the heat sink 260 is improved and the cooling efficiency of the semiconductor module 300 is improved. Step S300 may be omitted.

In step S400, the first semiconductor module cell 200a and the second semiconductor module cell 200b are mounted on the upper surface of the heat sink 260. The first semiconductor module cell 200a and the second semiconductor module cell 200b are mounted such that their side surfaces are in contact with each other. Thus, a frictional force acts between the first semiconductor module cell 200a and the second semiconductor module cell 200b and the pressing force applied to the first semiconductor module cell 200a and the second semiconductor module cell 200b are made uniform.

In step S500, the casing portion 210 is coupled to the heat sink 260 so as to cover the first semiconductor module cell 200a and the second semiconductor module cell 200b. Thus, the pressing portion 215 of the casing portion 210 applies the pressing force on the upper surface of the first semiconductor module cell 200a and the second semiconductor module cell 200b and the cooling efficiency of the semiconductor module 300 is improved.

FIG. 7B illustrates a flowchart of a method for manufacturing the semiconductor module cell 200. The method for manufacturing the semiconductor module cell 200 may be an example of step S100 for obtaining the first semiconductor module cell 200a or may be an example of step S200 for obtaining the second semiconductor module cell 200b.

The method for manufacturing the semiconductor module cell 200 includes a step S110 for providing the laminated substrate 150, step S120 for providing the semiconductor chip 100, step S130 for connecting the laminated substrate 150 to the semiconductor chip 100, and step S140 for pouring the encapsulating portion 220. The method for manufacturing the semiconductor module cell 200 may include step S150 for cutting the encapsulating portion 220. Step S110 for providing the laminated substrate 150 may be performed in a usual method that would be understood by one of ordinary skill in the art and its description is omitted in the present specification.

In step S120, the semiconductor chip 100 is provided above the laminated substrate 150. The semiconductor chip 100 may be mounted above the laminated substrate 150 in a quantity of one or in a quantity of two or more. As an example, the semiconductor chip 100 is mounted above the laminated substrate 150 to form the upper arm and lower arm of the semiconductor module cell 200. The coupling member 160 composed of solder or the like may be provided between the laminated substrate 150 and the semiconductor chip 100.

In step S130, the laminated substrate 150 is electrically connected to the semiconductor chip 100. The connection between the laminated substrate 150 and the semiconductor chip 100 may be achieved via the lead frame 230, or may be achieved via bonding wire or the like, or may be achieved via the coupling member 160.

In step S140, the semiconductor chip 100 is covered by the encapsulating portion 220. The pouring of the encapsulating portion 220 may be performed until the semiconductor chip 100 and the laminated substrate 150 are completely accommodated within the encapsulating portion 220. The pouring of the encapsulating portion 220 may be performed by using a cast.

In step S150, at least part of the end of the encapsulating portion 220 in the shorter direction is cut. The encapsulating portion 220 in the present example has one or more contact surfaces where its inclined side surface and that of another encapsulating portion are in contact with each other. The inclined side surface of the encapsulating portion 220 may be formed as a result of at least part of the encapsulating portion 220 being cut in step S150.

The inclined side surface of the encapsulating portion 220 may be formed in a method other than step S150 for cutting at least part of the encapsulating portion 220. As an example, the inclined side surface of the encapsulating portion 220 is formed by providing the inclination in the cast to be used for pouring the encapsulating portion 220 in step S140.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that the embodiments to which such alterations or improvements are made can be included in the technical scope of the present invention.

It should be noted that the operations, procedures, steps, stages, and the like of each process performed by an apparatus, system, program, and method shown in the claims, specification, or diagrams can be realized in any order as long as the order is not indicated by “prior to,” “before,” or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

100 semiconductor chip
110 output terminal
112 gate external terminal
114 auxiliary source external terminal
122 gate external terminal
124 auxiliary source external terminal
142 positive terminal
144 negative terminal
150 laminated substrate
151 first metal layer
152 insulating plate
153 second metal layer
160 coupling member
181 first placement region
182 second placement region
183 third placement region
200 semiconductor module cell
210 casing portion
215 pressing portion
220 lead frame
230 encapsulating portion
225 contact portion
226 contact surface
227 inclined section
228 vertical portion
240 coupling portion
250 interposed portion
260 heat sink
270 spring portion
300 semiconductor module.

What is claimed is:

1. A semiconductor apparatus comprising:
a heat sink;
a first semiconductor module cell which is provided above the heat sink;
a second semiconductor module cell which is provided above the heat sink and is provided to be in contact with the first semiconductor module cell; and
a casing portion which is coupled to the heat sink and accommodates the first semiconductor module cell and the second semiconductor module cell,
the first semiconductor module cell having:
a first laminated substrate;
a first semiconductor chip which is mounted on the first laminated substrate; and
a first encapsulating portion which covers the first semiconductor chip,
the second semiconductor module cell having:
a second laminated substrate;
a second semiconductor chip which is mounted on the second laminated substrate; and
a second encapsulating portion which covers the second semiconductor chip,
the semiconductor apparatus comprising a pressing portion for pressing upper surfaces of the first encapsulating portion and the second encapsulating portion, and
side surfaces of the first encapsulating portion and the second encapsulating portion being in contact with each other.

2. The semiconductor apparatus according to claim 1, wherein the first encapsulating portion and the second encapsulating portion have one or more contact surfaces where inclined side surfaces are in contact with each other.

3. The semiconductor apparatus according to claim 2, wherein an angle of a contact surface among any of the one or more contact surfaces relative to a laminating direction of the first laminated substrate and the second laminated substrate is 10° or more and 90° or less.

4. The semiconductor apparatus according to claim 2, wherein the one or more contact surfaces includes:
a first inclined section whose angle relative to a laminating direction of the first laminated substrate and the second laminated substrate is 10° or more and 90° or less; and
a second inclined section whose angle relative to a laminating direction of the first laminated substrate and the second laminated substrate is −90° or more and −10° or less.

5. The semiconductor apparatus according to claim 4, wherein an absolute value of the angle of the first inclined section is equal to an absolute value of the angle of the second inclined section.

6. The semiconductor apparatus according to claim 1, wherein the first encapsulating portion and the second encapsulating portion are provided in a mutually separatable manner with side surfaces being in contact with each other.

7. The semiconductor apparatus according to claim 1, wherein the casing portion has a plurality of coupling portions which couple to the heat sink.

8. The semiconductor apparatus according to claim 1, wherein the casing portion is separated from the first laminated substrate and the second laminated substrate.

9. The semiconductor apparatus according to claim 1, comprising an organic insulating interposed portion which is provided on an upper surface of the heat sink.

10. The semiconductor apparatus according to claim 9, wherein the first semiconductor module cell and the second semiconductor module cell are provided on one interposed portion, which is the interposed portion.

11. The semiconductor apparatus according to claim 1, comprising a third semiconductor module cell having:
a third laminated substrate;
a third semiconductor chip which is mounted on the third laminated substrate; and
a third encapsulating portion which covers the third semiconductor chip.

12. The semiconductor apparatus according to claim 11, wherein a side wall of the third encapsulating portion is in contact with at least one of a side wall of the first encapsulating portion or a side wall of the second encapsulating portion.

13. The semiconductor apparatus according to claim 1, wherein the pressing portion is an inner wall of the casing portion, and
the inner wall of the casing portion is in contact with the upper surface of the first encapsulating portion and the upper surface of the second encapsulating portion.

14. The semiconductor apparatus according to claim 2, wherein the pressing portion is an inner wall of the casing portion, and
the inner wall of the casing portion is in contact with the upper surface of the first encapsulating portion and the upper surface of the second encapsulating portion.

15. The semiconductor apparatus according to claim 3, wherein the pressing portion is an inner wall of the casing portion, and
the inner wall of the casing portion is in contact with the upper surface of the first encapsulating portion and the upper surface of the second encapsulating portion.

16. The semiconductor apparatus according to claim 4, wherein the pressing portion is an inner wall of the casing portion, and
the inner wall of the casing portion is in contact with the upper surface of the first encapsulating portion and the upper surface of the second encapsulating portion.

17. The semiconductor apparatus according to claim 1, wherein the pressing portion is a spring portion which is provided between the casing portion, and the first encapsulating portion and the second encapsulating portion.

18. A method for manufacturing a semiconductor apparatus, comprising:
obtaining a first semiconductor module cell having a first laminated substrate, a first semiconductor chip which is provided above the first laminated substrate, and a first encapsulating portion which is formed so as to cover the first semiconductor chip;
obtaining a second semiconductor module cell having a second laminated substrate, a second semiconductor chip which is provided above the second laminated substrate, and a second encapsulating portion which is formed so as to cover the second semiconductor chip;
mounting the first semiconductor module cell and the second semiconductor module cell on an upper surface of a heat sink to be in contact with each other; and
coupling a casing portion to the heat sink so as to cover the first semiconductor module cell and the second semiconductor module cell and pressing the first semiconductor module cell and the second semiconductor module cell against the heat sink by a pressing portion of the casing portion.

19. The method for manufacturing the semiconductor apparatus according to claim 18, comprising providing an organic insulating interposed portion on an upper surface of the heat sink.

20. The method for manufacturing the semiconductor apparatus according to claim 18,
wherein the obtaining the first semiconductor module cell includes:
providing the first semiconductor chip above the first laminated substrate;
electrically connecting the first laminated substrate to the first semiconductor chip;
pouring the first encapsulating portion so as to cover the first semiconductor chip; and
cutting at least part of an end of the first encapsulating portion in a shorter direction;
the obtaining the second semiconductor module cell including:
providing the second semiconductor chip above the second laminated substrate;
electrically connecting the second laminated substrate to the second semiconductor chip;
pouring the second encapsulating portion so as to cover the second semiconductor chip; and
cutting at least part of an end of the second encapsulating portion in a shorter direction,
wherein the first encapsulating portion and the second encapsulating portion have one or more contact surfaces where inclined side surfaces thereof are in contact with each other.
